(19) United States
(12) Patent Application Publication
(10) Pub. No.: US 2006/0113679 A1
(43) Pub. Date: Jun. 1, 2006

(54) Semiconductor device

(76) Inventors: Hiroyuki Takatsu, Nagano-shi (JP); Atsunori Kajiki, Nagano-shi (JP); Takashi Tsubota, Nagano-shi (JP); Norio Yamanishi, Nagano-shi (JP); Sadakazu Akaike, Nagano-shi (JP); Akinobu Inoue, Nagano-shi (JP)

Correspondence Address: LADAS & PARRY LLP, 224 SOUTH MICHIGAN AVENUE, SUITE 1600, CHICAGO, IL, 60604, US

(21) Appl. No.: 11/288,007

(22) Filed: Nov. 28, 2005

(30) Foreign Application Priority Data
Nov. 30, 2004 (JP) 2004-346847

(51) Int. Cl. H01L 23/48; H01L 23/52

(52) U.S. Cl. 257/778; 257/782; 257/777

(57) ABSTRACT

A semiconductor device includes a semiconductor chip, wirings, a substrate electrically connected to the semiconductor chip via the wirings and a plurality of discrete parts provided on a part of the substrate. The part is located closer to the center of the substrate than a wiring disposing area where the wirings are disposed.

### BACKGROUND OF THE INVENTION

1. Field of the Invention

The present invention generally relates to a semiconductor device, especially to a semiconductor device including a semiconductor chip connected to a substrate according to a wire bonding method and plural discrete parts disposed on the substrate.

2. Description of the Related Art

The conventional semiconductor device includes a substrate, plural semiconductor chips and plural discrete parts, in which the semiconductor chips and the discrete parts are mounted on the substrate. Some of the semiconductor devices include a semiconductor chip connected to a substrate according to the wire bonding method. Moreover, according to the demands for high-density mounting and size reduction in recent years, as shown in FIGS. 1 through 3 described below, plural semiconductor chips are laminated (a stack structure) in the thickness direction of the substrate so as to realize high-density mounting and size reduction of the semiconductor device.

Next, with reference to FIGS. 1 through 3, a description is given of configurations of conventional semiconductor devices. FIGS. 1 through 3 are cross-sectional views illustrating the conventional semiconductor devices. An area A (hereinafter, referred to as “Area A”) shown in FIG. 1 part is located closer to a center of the substrate than a wiring disposing area in which a wiring 34 is disposed (area in which a second connection pad 16 is disposed). An area B (hereinafter, referred to as “Area B”) shown in FIG. 2 is located closer to a center of the substrate than a wirings disposing area in which wirings 57 through 59 are disposed (area in which a third connection pad 44 is disposed). An area C (hereinafter, referred to as “Area C”) is located closer to a center of the substrate than a wiring disposing area in which a wiring 87 is disposed (area in which a second connection pad 73 is disposed). It should be noted that in FIGS. 2 and 3, the same components of the semiconductor device 10 as shown in FIG. 1 are given the same reference numbers.

As shown in FIG. 1, the semiconductor device 10 includes a substrate 11, a first semiconductor chip 27, a second semiconductor chip 32 and plural discrete parts 36. The substrate 11 includes a base member 12, a penetrating via 13 penetrating the base member 12, a first connection pad 15 and a second connection pad 16 provided on the upper face of the base member 12, a connection pad 17 for the discrete parts, solder resist 18, a wiring 21 disposed on the under face of the base member 12, solder resist 24 and a solder ball 25. The connection pad 17 to which the discrete parts 36 are connected is disposed outside of Area A on the base member 12.

A first semiconductor chip 27 includes an electrode pad 28. The electrode pad 28 and the first connection pad 15 are connected by a flip chip linkage. A second semiconductor chip 32 larger than the first semiconductor chip 27 includes an electrode pad 33. The electrode pad 33 is connected to the second connection pad 16 via the wiring 34. The second semiconductor chip 32 is bonded to the first semiconductor chip 27 by an adhesive 31. The plural discrete parts 36 are connected to the connection pad 17 for the discrete parts by solder paste 37. The discrete parts 36 are basic electronic elements such as a transistor, a diode, a resistor, a capacitor and the like. The first semiconductor chip 27, the second semiconductor chip 32 and the discrete parts 36 are covered with resin 39 so as to protect the wiring 34.

As shown in FIG. 2, a semiconductor device 40 includes a substrate 41 on which first through third connection pads 42 through 44 are mounted, first through third semiconductor chips 46, 49 and 54 having different sizes among others, and plural discrete parts 36. The first semiconductor chip 46 which is the largest of the three is disposed on the upper face of the base member 12. An electrode pad 47 disposed on the first semiconductor chip 46 is connected to the first connection pad 42 via the wiring 57.

The second semiconductor chip 49 which is the second largest of the three is disposed on the first semiconductor chip 46. An electrode pad 51 disposed on the second semiconductor chip 49 is connected to the second connection pad 43 via the wiring 58. The third semiconductor chip 54 which is the smallest of the three is disposed on the second semiconductor chip 49. An electrode pad 55 disposed on the third semiconductor chip 54 is connected to the third connection pad 44 via the wiring 59. The discrete parts 36 are electrically connected to the connection pad 17 for the discrete parts disposed outside of Area B via the solder paste 37 (for example, see Patent Document 1).

As shown in FIG. 3, a semiconductor device 70 includes a substrate 71 on which a first connection pad 72 and a second connection pad 73 are mounted, a first semiconductor chip 76 and a second semiconductor chip 85 having different sizes among others, a spacer 82 and plural discrete parts 36. The first semiconductor chip 76 smaller than the second semiconductor chip 85 is disposed on the upper face of the base member 12. An electrode pad 77 disposed on the first semiconductor chip 76 is connected to the first connection pad 72 by a wiring 78.

A spacer 82 is disposed on the first semiconductor chip 76. The spacer 82 is provided for supporting the second semiconductor chip 85 and adjusting a disposing position of the second semiconductor chip 85 in the height direction so as to prevent the wiring 78 from contacting the second semiconductor chip 85.

The second semiconductor chip 85 is disposed on the spacer 82. An electrode pad 86 disposed on the second semiconductor chip 85 is connected to the second connection pad 73 via the wiring 87. The discrete parts 36 are electrically connected to the connection pad 17 for the discrete parts disposed outside of Area C via the solder paste 37.

Such semiconductor devices are disclosed in Japanese Laid-Open Patent Application No. 2004-214258 (Patent Document 1).

There are demands for further high-density mounting and size reduction of the semiconductor device. However; it is difficult to realize the further high-density mounting and size reduction by the conventional semiconductor devices 10, 40 and 70 to which the stack structure is applied.

### SUMMARY OF THE INVENTION

The present invention provides a semiconductor device realizing the high-density mounting and the size reduction that substantially obviates one or more problems caused by the limitations and disadvantages of the related art.

Features and advantages of the present invention are presented in the description which follows, and in part will become apparent from the description and the accompanying drawings, or may be learned by practice of the invention according to the teachings provided in the description. Objects as well as other features and advantages of the present invention will be realized and attained by the semiconductor device particularly pointed out in the specification in such full, clear, concise, and exact terms as to enable a person having ordinary skill in the art to practice the invention.

To achieve these and other advantages in accordance with the purpose of the invention, the invention provides a semiconductor device including a semiconductor chip, wirings, a substrate electrically connected to the semiconductor chip via the wirings and a plurality of discrete parts provided on a part of the substrate. The part is located closer to the center of the substrate than a wiring disposing area where the wirings are disposed.

According to at least one of the embodiments of the present invention, the plural discrete parts are disposed on the part of the substrate closer to the center than the wiring disposing area where the wirings are disposed so as to realize a high-density mounting and a size reduction of the semiconductor device.

### BRIEF DESCRIPTION OF THE DRAWINGS

Other objects and further features of the present invention will become apparent from the following detailed description when read in conjunction with the accompanying drawings, in which:

FIG. 1 is a cross-sectional view illustrating a conventional semiconductor device;

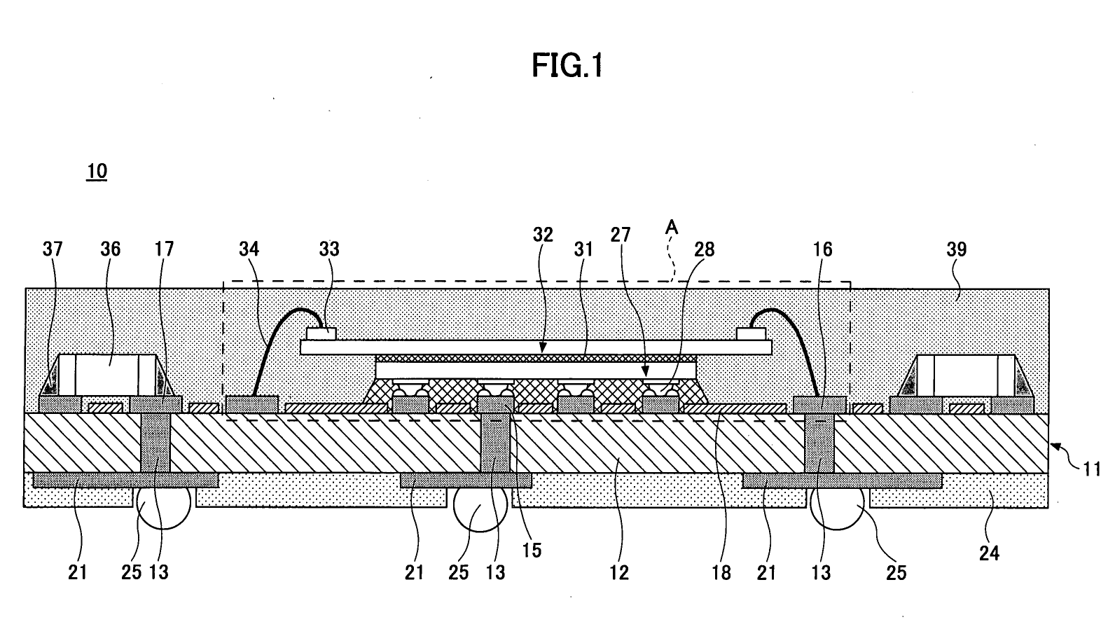

FIG. 2 is a cross-sectional view illustrating another conventional semiconductor device;

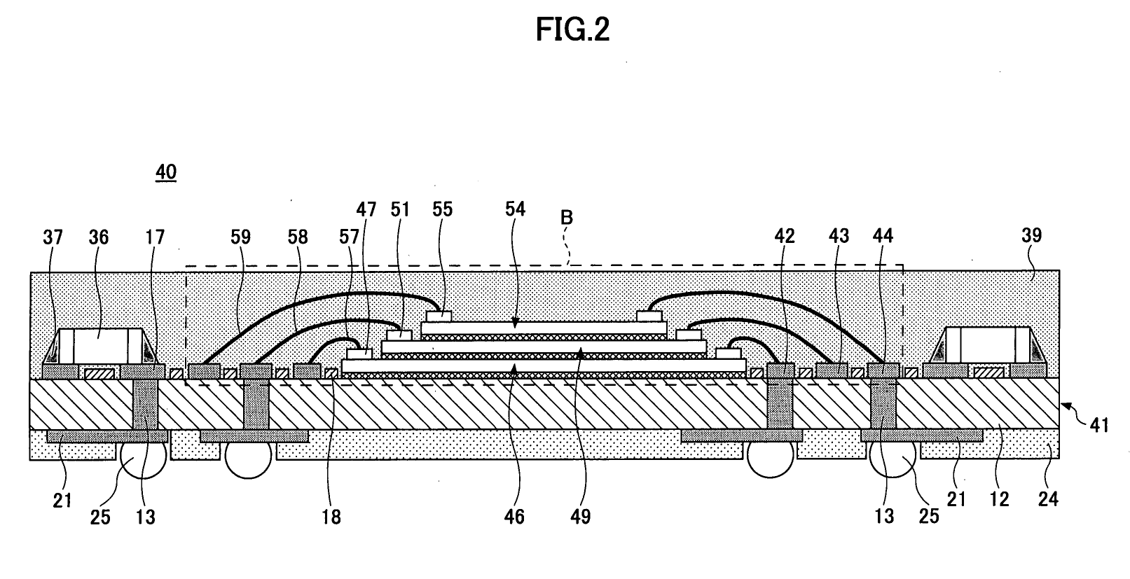

FIG. 3 is a cross-sectional view illustrating yet another conventional semiconductor device;

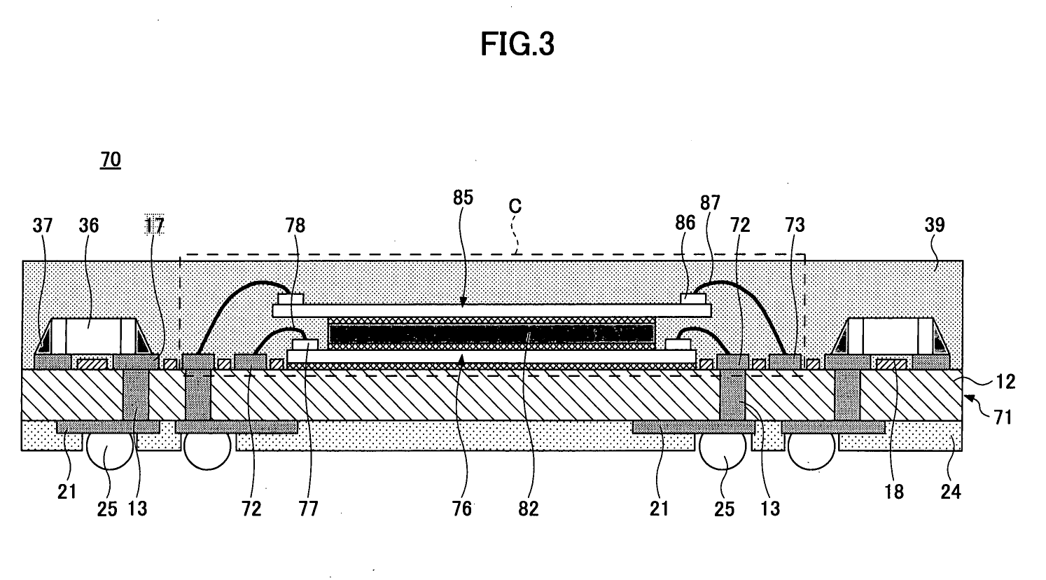

FIG. 4 is a cross-sectional view illustrating a semiconductor device according to a first embodiment of the present invention;

FIG. 5 is a plan view of the semiconductor device shown in FIG. 4 illustrating a position relationship between discrete parts and a semiconductor chip;

FIG. 6 is a cross-sectional view illustrating a modified example of the first embodiment;

FIG. 7 is a cross-sectional view of a semiconductor device according to a second embodiment of the present invention; and

FIG. 8 is a plan view of the semiconductor device shown in FIG. 7 illustrating a positional relationship between the discrete parts and the semiconductor chip.

### DESCRIPTION OF THE PREFERRED EMBODIMENTS

In the following, embodiments of the present invention are described with reference to the accompanying drawings.

### First Embodiment

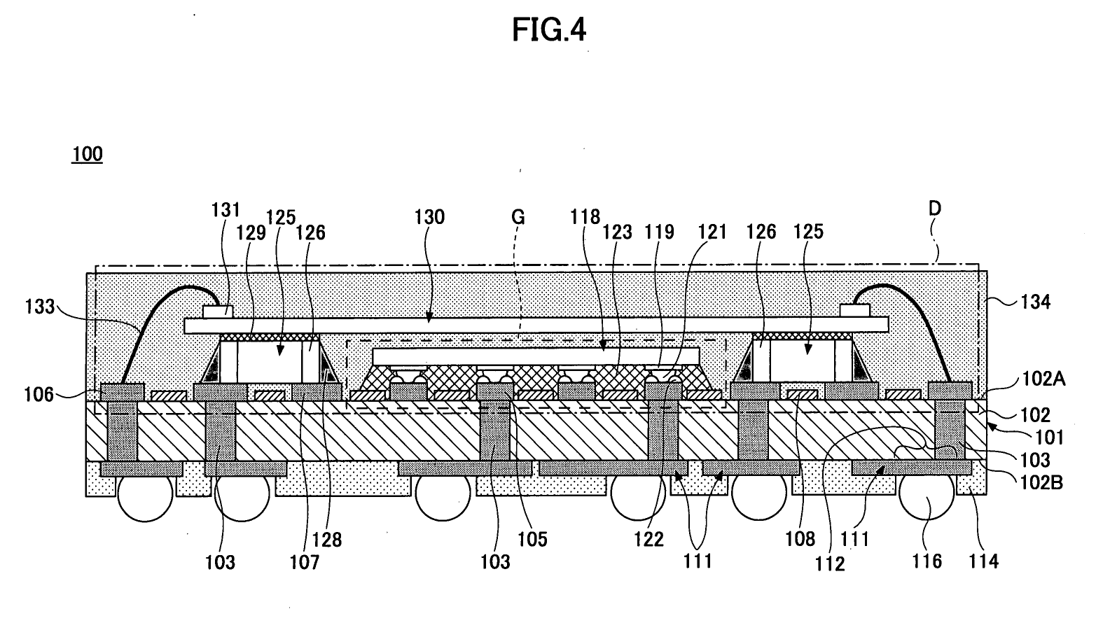

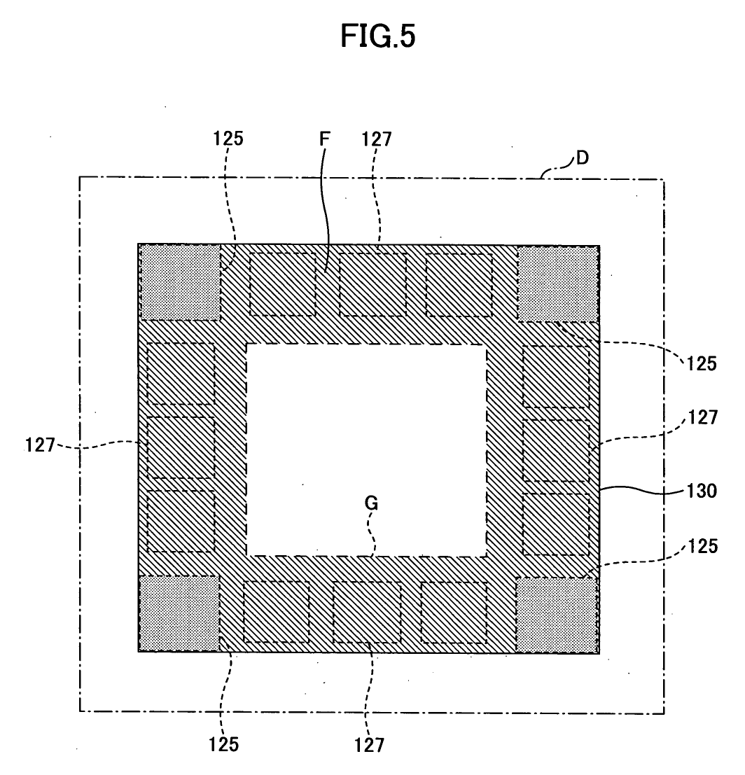

With reference to FIGS. 4 and 5, a description is given of a semiconductor device 100 according to the first embodiment of the present invention. FIG. 4 is a cross-sectional view illustrating the semiconductor device 100 according to the first embodiment of the present invention. FIG. 5 is a plan view of the semiconductor device illustrating a position relationship between discrete parts shown in FIG. 4 and a semiconductor chip. An area D (hereinafter, referred to as “Area D”) shown in FIGS. 4 and 5 contains a wiring disposing area (the second connection pad 106 is disposed). An area G (hereinafter, referred to as Area G) shown in FIGS. 4 and 5 is an area in which a first semiconductor chip 118 is disposed (hereinafter, referred to as “First Semiconductor Chip Disposing Area G”). The Area G is located closer to a center of the substrate than the Area D. Further, a hatched part F shown in FIG. 5 is a space (hereinafter, referred to as “Space F”) formed between a second semiconductor chip 130 and the periphery of a substrate 101.

The semiconductor device 100 includes the substrate 101, the first semiconductor chip 118, the second semiconductor chip 130 and plural discrete parts 125 and 127. It should be noted that the first semiconductor chip 118, the second semiconductor chip 130, and the discrete parts 125 and 127 are sealed by resin 134 so as to protect a wiring 133 described below.

The substrate 101 is an interposer including a base member 102, a penetrating via 103, a first connection pad 105, a second connection pad 106, a connection pad 107 for the discrete parts, solder resist 108, a wiring 111, solder resist 114 and a solder ball 116. The penetrating via 103 is provided protruding through the base member 102. The penetrating via 103 is provided for electrically connecting the first connection pad 105, the second connection pad 106, and the connection pad 107 for the discrete parts and the wiring 111. It should be noted that as the base member 102, a resin member, a ceramic member, a glass member and the like can be used.

The first connection pad 105 is disposed on the upper face 102A of the base member 102 at substantially the center of Area D. The first connection pad 105 is electrically connected to the penetrating via 103. The first connection pad 105 is provided for mounting the first semiconductor chip 118. The second connection pad 106 is disposed in Area D on the base member 102 apart from the first connection pad 105. The second connection pad 106 is electrically connected to the penetrating via 103. The second connection pad 106 is electrically connected to the second semiconductor chip 130 via the wiring 133. As for the wiring 133, for example, Au wiring can be used.

The connection pad 107 for the discrete parts is provided on the base member 102 between the first connection pad 105 and the second connection pad 106. The connection pad 107 for the discrete parts is electrically connected to the discrete parts 125 and 127.

The solder resist 108 is formed on the upper face 102A of the base member 102 excluding the parts on which the first connection pad 105, the second connection pad 106, the connection pad 107 for the discrete parts are provided. The wiring 111 including a connection part 112 is disposed on the under face 102B of the base member 102 so as to be electrically connected to the penetrating via 103. The solder resist 114 is disposed on the under face 102B of the base member 102 so as to cover the wiring 111 other than the connection part 112. The solder ball 116 is disposed on the connection part 112. The solder ball 116 is an external connection terminal provided for connecting another substrate such as a motherboard.

The first semiconductor chip 118 includes an electrode pad 119. The electrode pad 119 and the connection pad 105 are connected by a flip flop linkage. Specifically, a stud bump 121 disposed on the electrode pad 119 is connected to the first connection pad 105 via solder 122. Underfill resin 123 fills a space between the first semiconductor chip 118 and the substrate 101. The underfill resin 123 is provided for preventing a mismatch of the coefficients of the thermal expansion between the first semiconductor chip 118 and the substrate 101. The first semiconductor chip 118 is disposed on the substrate 101 opposing the second semiconductor chip 130. Accordingly, the first semiconductor chip 118 is disposed on the substrate 101 opposing the second semiconductor chip 130 so as to realize a high-density mounting. It should be noted that the thickness of the first semiconductor chip 118 is, for example, 100 μm through 300 μm.

The second semiconductor chip 130 larger than the first semiconductor chip 118 is connected to the substrate 101 according to the wire bonding method. The second semiconductor chip 130 includes an electrode pad 131. The side of the second semiconductor chip 130 to which the electrode pad 131 is not bonded is connected to the discrete part 125 by the adhesive 129. Moreover, the electrode pad 131 is electrically connected to the second connection pad 106 via the wiring 133.

The second semiconductor chip 130 is supported by four discrete parts 125 having substantially the same height onto the substrate 101. Accordingly, the four corners of the second semiconductor chip 130 are supported by the four discrete parts 125 having substantially the same height so as to support the second semiconductor chip 130 stably. Thereby, the wiring 133 can be disposed precisely. It should be noted that the second semiconductor chip 130 can be supported by more than four discrete parts 125. The thickness of the semiconductor chip 130 is, for example, 100 μm through 300 μm.

Next, a description is given of the plural discrete parts 125 and 127. The discrete parts 125 and 127 according to the present embodiment are electric elements being a basis of a transistor, a diode, a resistor, a capacitor and the like. One part plays one function.

The discrete part 125 includes an electrode 126. The electrode 126 and the connection pad 107 for the discrete parts are electrically connected by solder paste 128. The discrete part 125 is higher than the discrete parts 127. The height of the discrete parts 125 are, for example, 0.3 mm through 1.0 mm. The four discrete parts 125 are disposed at positions where the four corners of the second semiconductor chip 130 can be supported on the substrate 101. The discrete parts 125 and the second semiconductor chip 130 are bonded by the adhesive 129. The second semiconductor chip 130 is disposed at a higher position than the first semiconductor chip 118. The discrete parts 127 are electrically connected to the connection pad (not shown) for the discrete parts on the substrate 101.

Accordingly, the higher discrete parts 125 of the plural discrete parts 125 and 127 (the highest discrete parts) support the second semiconductor chip 130. Space F is provided between the second semiconductor chip 130 and the substrate 101. The plural discrete parts 127 are disposed on the substrate 101 corresponding to Space F so as to realize a high-density mounting. It should be noted that the connection pad 107 for the discrete parts which is conventionally disposed outside of Area D is disposed in Area D so as to reduce the size of the semiconductor device 100.

Further, the discrete parts 127 can be disposed jutting out the external shape of the second semiconductor chip 130 so as to be prevented from contacting the wiring 133. Moreover, when the discrete parts are disposed in the thickness direction of the base member 102, the largest semiconductor chip is connected to the substrate 101 by the wire bonding method. As a result, an effect similar to the present embodiment can be obtained. Furthermore, when the discrete parts have more than two heights, the second semiconductor chip 130 can be supported by the highest of the discrete parts.

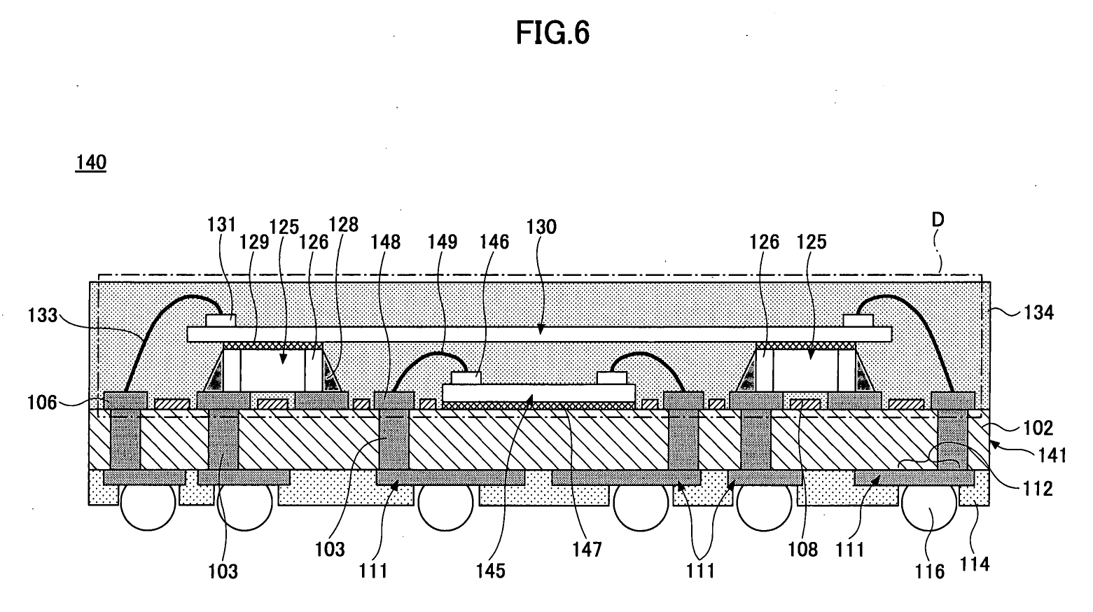

FIG. 6 is a cross-sectional view illustrating a modified example of the semiconductor device of the first embodiment. It should be noted that in FIG. 6, the same components of the semiconductor device 100 as shown in FIG. 4 are given the same reference numbers. As shown in FIG. 6, the semiconductor device 140 is configured to include a first semiconductor chip 145 smaller than the second semiconductor chip 130 bonded to a substrate 141 by adhesive 147 and connected to an electrode pad 146 mounted on the first semiconductor chip 145 and a first connection pad 148 by a wiring 149. In such a configuration of the semiconductor device 140, an effect similar to the first semiconductor device 100 of the first embodiment can be obtained.

### Second Embodiment

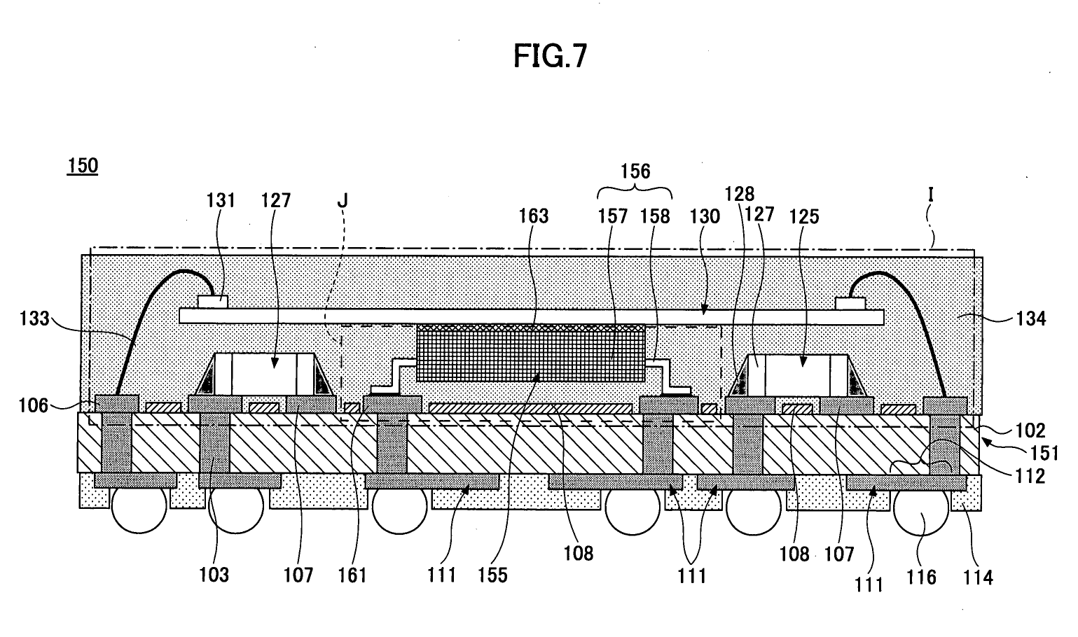

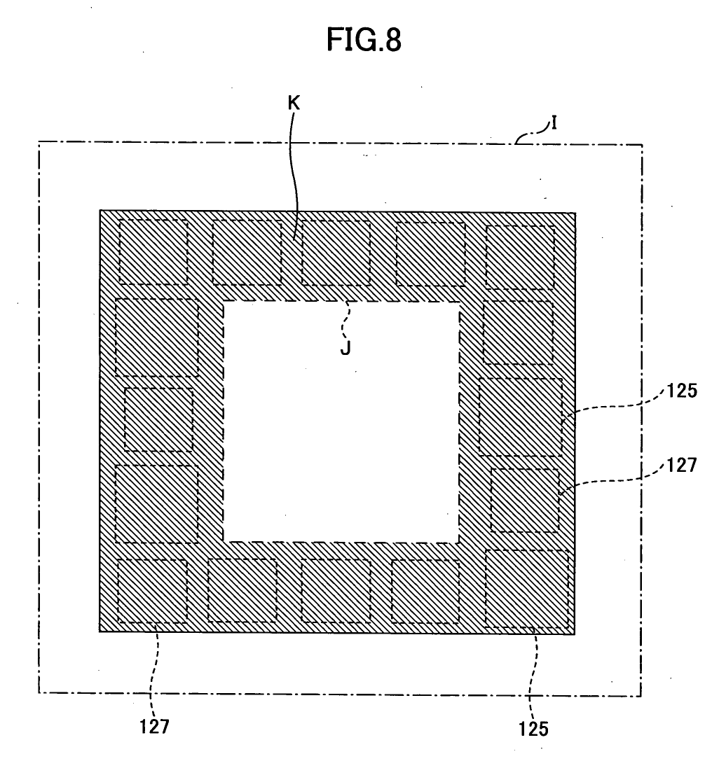

With reference to FIGS. 7 and 8, a description is given of a semiconductor device 150 according to the second embodiment of the present invention. FIG. 7 is a cross-sectional view of a semiconductor device according to the second embodiment of the present invention. FIG. 8 is a plan view of the semiconductor device illustrating a positional relationship between the discrete parts and the semiconductor chip. It should be noted that an area I (hereinafter, referred to as “Area I”) shown in FIGS. 7 and 8 includes a wiring disposing area (an area where the second connection pad 106 is disposed). An area J is where a package chip 155 is disposed (hereinafter, referred to as “a Package Chip Mounting Area J”). The Area J is located closer to a center of the substrate than the Area I. Further, a space K shown by hatching is formed between the second semiconductor chip 130 and the substrate 101 (hereinafter, referred to as “Space K”). It should be noted that in FIG. 7, the same components of the semiconductor device 100 as shown in FIG. 4 are given the same reference numbers.

The semiconductor device 150 includes a substrate 151, the package chip 155, the second semiconductor chip 130 and plural discrete parts 125 and 127. The second semiconductor chip 130, the discrete parts 125 and 127, and the package chip 155 disposed on the substrate 151 are sealed by resin 134.

The substrate 151 includes a first connection pad 161 disposed at substantially the center of Area I on the base member 102. The first connection pad 161 and the package chip 155 are electrically connected. The package chip 155 includes a semiconductor chip (not shown) and a package 156. The package 156 includes a package main body 157 and a lead frame 158. The upper face of the package main body 157 is flat. In the inside of the package main body 157, a semiconductor chip (not shown) is mounted. The lead frame 158 is electrically connected to the semiconductor chip mounted in the package main body 157. Moreover, the lead frame 158 is electrically connected to the first connection pad 161 by solder. Furthermore, the second semiconductor chip 130 is bonded to the upper face of the package main body 157 by adhesive 163. The second semiconductor chip 130 is supported by the package chip 155 onto the substrate 151.

It should be noted that as the package chip 155, it is desirable to select a package chip wherein Package Chip Mounting Area J is smaller than the outer shape of the second semiconductor chip 130. In addition, the package chip 155 is higher than the discrete parts 125 and 127. Accordingly, the package chip 155 including Package Chip Mounting Area J smaller than the outer shape of the second semiconductor chip 130 supports the second semiconductor chip 130, and thereby, forms Space K between the second semiconductor chip 130 and the substrate 151. The discrete parts 125 and 127 are disposed on the substrate 151 corresponding to Space K. Therefore, a high-density mounting can be realized. Further, the connection pad 107 for the discrete parts which is conventionally disposed outside of Area I is disposed in Area I so as to reduce the size of the semiconductor device 150.

In FIG. 7, SOP (small outline package) is shown as an example of a form of the package 156. As the package 156, for example, CSP (chip size package), BGA (ball grid array), SOJ (small outline j-leaded package) and the like can be used. Further, the discrete parts 125 and 127 can be disposed jutting out the outer shape of the second semiconductor chip 130 so as to prevent the discrete parts 125 and 127 from contacting the wiring 133. Moreover, when plural of the semiconductor chips are disposed in the thickness direction of the base member 102, the largest semiconductor chip is connected to the substrate 151 according to the wire bonding method so as to obtain an effect similar to the present embodiment.

According to at least one of the embodiments of the present invention, the semiconductor chip is supported by at least four of the discrete parts so that the semiconductor chip can be supported stably on the substrate.

According to at least one of the embodiments of the present invention, the semiconductor chip is supported by the highest discrete parts so that the other discrete parts can be disposed on the substrate opposing the semiconductor chip.

According to at least one of the embodiments of the present invention, between the semiconductor chip and the substrate, another semiconductor chip is provided so as to realize a high-density mounting.

According to at least one of the embodiments of the present invention, the semiconductor chip is supported by a package higher than the discrete parts so as to dispose the discrete parts on the substrate opposing the semiconductor chip.

Therefore, a semiconductor device realizing high-density mounting and size reduction can be provided according to the present invention.

Further, the present invention is not limited to these embodiments, but variations and modifications may be made without departing from the scope of the present invention. It should be noted that the first embodiment and the second embodiment can be applied to a semiconductor device on which the solder ball 116 is not mounted.

The present application is based on Japanese Priority Application No. 2004-346847 filed on Nov. 30, 2004, with the Japanese Patent Office, the entire contents of which are hereby incorporated by reference.

What is claimed is:

1. A semiconductor device comprising:
a semiconductor chip;
wirings;
a substrate electrically connected to the semiconductor chip via the wirings; and
a plurality of discrete parts provided on a part of the substrate; wherein said part is located closer to a center of the substrate than a wiring disposing area where said wirings are disposed.

2. The semiconductor device as claimed in claim 1, wherein said semiconductor chip is supported by at least four of the discrete parts on the substrate.

3. The semiconductor device as claimed in claim 1, wherein when heights of said discrete parts vary, said semiconductor chip is supported by the highest discrete parts on the substrate.

4. The semiconductor device as claimed in claim 1, wherein another semiconductor chip is provided between said semiconductor chip and said substrate.

5. The semiconductor device as claimed in claim 4, wherein said semiconductor chip is supported on the substrate by a package storing said other semiconductor chip, said package being higher than the discrete parts.
